(19) United States
(12) Patent Application Publication
(10) Pub. No.: US 2010/0248142 A1
(43) Pub. Date: Sep. 30, 2010

(54) LITHOGRAPHIC PRINTING PLATE PRECURSOR AND PLATE MAKING METHOD THEREOF

(76) Inventor: Katsuya TAKEMASA, Shizuoka (JP)

Correspondence Address: BIRCH STEWART KOLASCH & BIRCH, PO BOX 747, FALLS CHURCH, VA, 22040-0747, US

(21) Appl. No.: 12/749,086

(22) Filed: Mar. 29, 2010

(30) Foreign Application Priority Data
Mar. 30, 2009 (JP) 2009-083711

(51) Int. Cl. G03F 7/004; G03F 7/20

(52) U.S. Cl. 430/281.1; 430/302

(57) ABSTRACT

A lithographic printing plate precursor includes, in the following order: a support; an image-recording layer which is capable of being removed with at least one of printing ink and dampening water and contains a polymerizable compound represented by the formula (1) as defined herein, a polymer particle containing a structural unit represented by the formula (2) as defined herein and a structural unit represented by the formula (3) as defined herein, an infrared absorbing agent and a polymerization initiator; and an overcoat layer.

### FIELD OF THE INVENTION

The present invention relates to a lithographic printing plate precursor and a plate making method using the same. More particularly, it relates to a lithographic printing plate precursor capable of undergoing a direct plate making by image exposure with laser and a plate making method comprising on-press development of the lithographic printing plate precursor.

### BACKGROUND OF THE INVENTION

In general, a lithographic printing plate is composed of an oleophilic image area accepting ink and a hydrophilic non-image area accepting dampening water (fountain solution) in the process of printing. Lithographic printing is a printing method utilizing the nature of water and oily ink to repel with each other and comprising rendering the oleophilic image area of the lithographic printing plate to an ink-receptive area and the hydrophilic non-image area thereof to a dampening water-receptive area (ink-unreceptive area), thereby making a difference in adherence of the ink on the surface of the lithographic printing plate, depositing the ink only to the image area, and then transferring the ink to a printing material, for example, paper.

In order to produce the lithographic printing plate, a lithographic printing plate precursor (PS plate) comprising a hydrophilic support having provided thereon an oleophilic photosensitive resin layer (image-recording layer) is used. Specifically, the PS plate is exposed through a mask, for example, a lith film, and then subjected to development processing, for example, with an alkaline developer to remove the unnecessary image-recording layer corresponding to the non-image area by dissolving while leaving the image-recording layer corresponding to the image area, thereby obtaining the lithographic printing plate.

Due to the recent progress in the technical field, nowadays the lithographic printing plate can be obtained by a CTP (computer-to-plate) technology. Specifically, a lithographic printing plate precursor is directly subjected to scanning exposure using laser or laser diode without using a lith film and developed to obtain a lithographic printing plate.

With the progress described above, the issue on the lithographic printing plate precursor has transferred to improvements, for example, in image-forming property corresponding to the CTP technology, printing property or physical property. Also, with the increasing concern about global environment, as another issue on the lithographic printing plate precursor, an environmental problem on waste liquid discharged accompanying the wet treatment, for example, development processing comes to the front.

In response to the environmental problem, simplification of development or plate making or non-processing has been pursued. As one method of simple plate making, a method referred to as an “on-press development” is practiced. Specifically, according to the method after exposure of a lithographic printing plate precursor, the lithographic printing plate precursor is mounted as it is on a printing machine without conducting conventional development and removal of the unnecessary area of image-recording layer is performed at an early stage of printing step.

Also, as a method of simple development, a method referred to as a “gum development” is practiced wherein the removal of the unnecessary area of image-recording layer is performed using not a conventional high alkaline developer but a finisher or gum solution of near-neutral pH.

In the simplification of plate making operation as described above, a system using a lithographic printing plate precursor capable of being handled in a bright room or under a yellow lump and a light source is preferable from the standpoint of workability. Thus, as the light source, a semiconductor laser emitting an infrared ray having a wavelength of 760 to 1,200 or a solid laser, for example, YAG laser, is used. An UV laser is also used.

As the lithographic printing plate precursor capable of undergoing on-press development, for example, a lithographic printing plate precursor having provided on a hydrophilic support, an image-forming layer in which hydrophobic thermoplastic polymer particles are dispersed in a hydrophilic binder is described (see, for example, Japanese Patent 2938397). The lithographic printing plate precursor is exposed to an infrared laser to agglomerate the hydrophobic thermoplastic polymer particles by heat thereby forming an image and mounted on a plate cylinder of a printing machine to be able to carry out on-press development by supplying dampening water and/or ink. Although the method of forming image by the agglomeration of fine polymer particles only upon thermal fusion shows good on-press development property, it has a problem in that the image strength is extremely weak and printing durability is insufficient.

In order to improve the printing durability of lithographic printing plate precursor capable of undergoing on-press development, a lithographic printing plate precursor having provided on a hydrophilic support, an image-recording layer (heat-sensitive layer) containing microcapsules having a polymerizable compound encapsulated therein is known (see JP-A-2001-277740 (the term “JP-A” as used herein means an “unexamined published Japanese patent application”) and JP-A-2001-277742). Also, a lithographic printing plate precursor having provided on a support, an image-recording layer (photosensitive layer) containing an infrared absorbing agent, a radical polymerization initiator and a polymerizable compound is known (see JP-A-2002-287334).

Moreover, various proposals have been made in order to improve the on-press development property and printing durability. For instance, it is proposed that an inorganic stratiform compound, for example, mica is incorporated into an overcoat layer on an image-recording layer to improve oxygen blocking property (see JP-A-2005-119273). It is also proposed that a copolymer having a repeating unit (a1) containing at least one ethylenically unsaturated bond and a repeating unit (a2) containing at least one functional group capable of interacting with a surface of support is incorporated into an undercoat layer provided between an image-recording layer and the support or the image-recording layer (see JP-A-2005-125749). Further, it is proposed that a urethaneacrylate is used as a polymerizable compound (see U.S. Patent Publication No. 2008/0254387).

However, the above-described techniques are still insufficient in view of compatibility between the on-press development property and printing durability and further improvements are desired.

### SUMMARY OF THE INVENTION

An object of the present invention is to provide a lithographic printing plate precursor of on-press development type which is capable of being subjected to image recording with laser exposure and is excellent in the on-press development property and printing durability.

(1) A lithographic printing plate precursor comprising a support, an image-recording layer which can be removed with printing ink, dampening water or both of them and which contains (A) a polymerizable compound represented by formula (1) shown below, (B) a fine polymer particle containing a structural unit represented by formula (2) shown below and a structural unit represented by formula (3) shown below, (C) an infrared absorbing agent and (D) a polymerization initiator and an overcoat layer in this order.

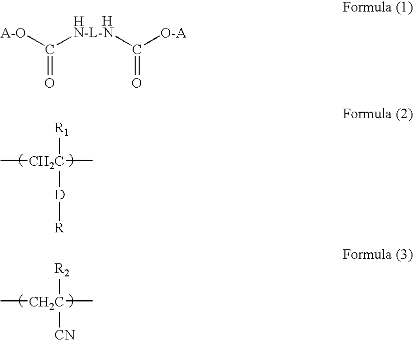

In the formulae, A represents a group containing from 1 to 3 ethylenically unsaturated groups, and L represents an alkylene group having from 5 to 9 carbon atoms.

R represents an alkyl group having from 1 to 12 carbon atoms, an aryl group or an aralkyl group, D represents a single bond or a —COO— group, and R₁ and R₂ each independently represents a hydrogen atom or a methyl group.

(2) The lithographic printing plate precursor as described in (1) above, wherein the overcoat layer contains an inorganic stratiform compound.
(3) The lithographic printing plate precursor as described in (1) or (2) above, wherein an undercoat layer containing a polymer compound having a support-adsorbing group and a polymerizable group is provided between the support and the image-recording layer.
(4) The lithographic printing plate precursor as described in any one of (1) to (3) above, wherein the image-recording layer contains at least any of a betaine compound represented by formula (I) shown below and a betaine compound represented by formula (II) shown below.

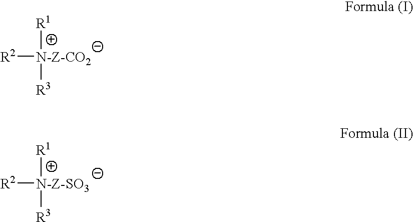

In formulae (I) and (II), R¹ to R³ each independently represents an alkyl group having from 1 to 5 carbon atoms, an alkenyl group, an alkynyl group, a cycloalkyl group or an aryl group, each of which may be substituted with a hydroxy group or an amino group, Z represents an alkylene group having from 1 to 4 carbon atoms which may be substituted with an alkyl group having 4 or less carbon atoms or a hydroxy group, or at least two of R¹ to R³ and Z may be combined with each other to from a heterocyclic ring.

(5) A plate making method comprising mounting the lithographic printing plate precursor as described in any one of (1) to (4) above on a printing machine and exposing imagewise it with infrared laser or exposing imagewise the lithographic printing plate precursor as described in any one of (1) to (4) above and mounting it on a printing machine, and then supplying printing ink, dampening water or both of them to remove an infrared unexposed area of the image-recording layer.

According to the present invention, a lithographic printing plate precursor of on-press development type which is capable of being subjected to image recording with laser exposure and is excellent in the on-press development property and printing durability can be provided.

### DETAILED DESCRIPTION OF THE INVENTION

### Lithographic Printing Plate Precursor

The lithographic printing plate precursor according to the invention comprises a support, an image-recording layer and an overcoat layer in this order, the image-recording layer is an image-recording layer which can be removed with printing ink, dampening water or both of them and which contains (A) a polymerizable compound represented by formula (1), (B) a fine polymer particle containing a structural unit represented by formula (2) and a structural unit represented by formula (3), (C) an infrared absorbing agent and (D) a polymerization initiator and it is preferable that the overcoat layer contains an inorganic stratiform compound. It is preferred that the lithographic printing plate precursor according to the invention comprises an undercoat layer between the support and the image-recording layer.

### (Image-Recording Layer)

Each of the components contained in the image-recording layer will be described in order below.

### (A) Polymerizable Compound Represented by Formula (1)

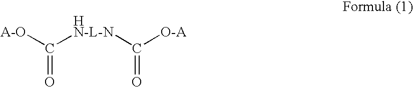

In formula (1), A represents a group containing 1 to 3 ethylenically unsaturated groups, and L represents an alkylene group having from 5 to 9 carbon atoms.

A is preferably a group represented by formula (a) shown below.

-M(-X)ₘ (a)

In formula (a), X represents an acryloyloxy group or a methacryloyloxy group.

m represents an integer of 1 to 3, and when plural Xs are present in formula (a), Xs independently represent an acryloyloxy group or a methacryloyloxy group.

M represents a connecting group formed by combination of groups shown below. M is particularly preferably an alkylene group having from 2 to 6 carbon atoms.

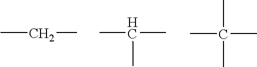

L is an alkylene group having from 5 to 9 carbon atoms formed by combination of groups shown below.

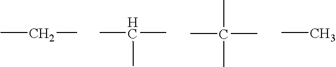

Preferable examples of L include structures represented by formulae (4) and (5) shown below.

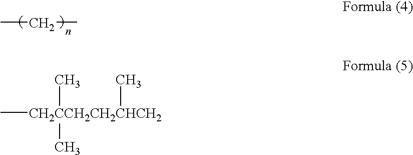

In formula (4), n represents an integer of 5 to 9. The alkylene group represented by L includes particularly preferably the alkylene group represented by formula (4) wherein n is 6 and the alkylene group represented by formula (5).

Specific examples of the polymerizable compound represented by formula (1) are set forth below, but the invention should not be construed as being limited thereto.

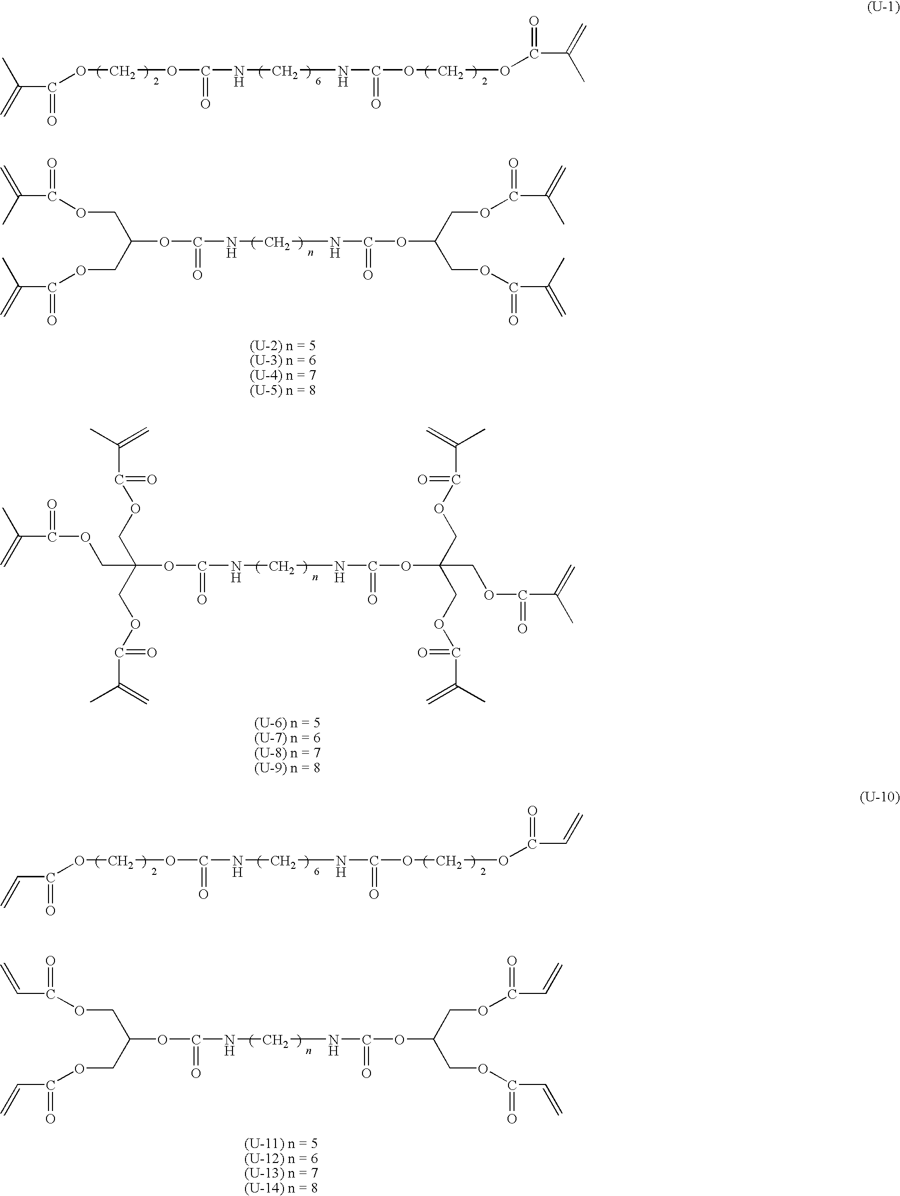

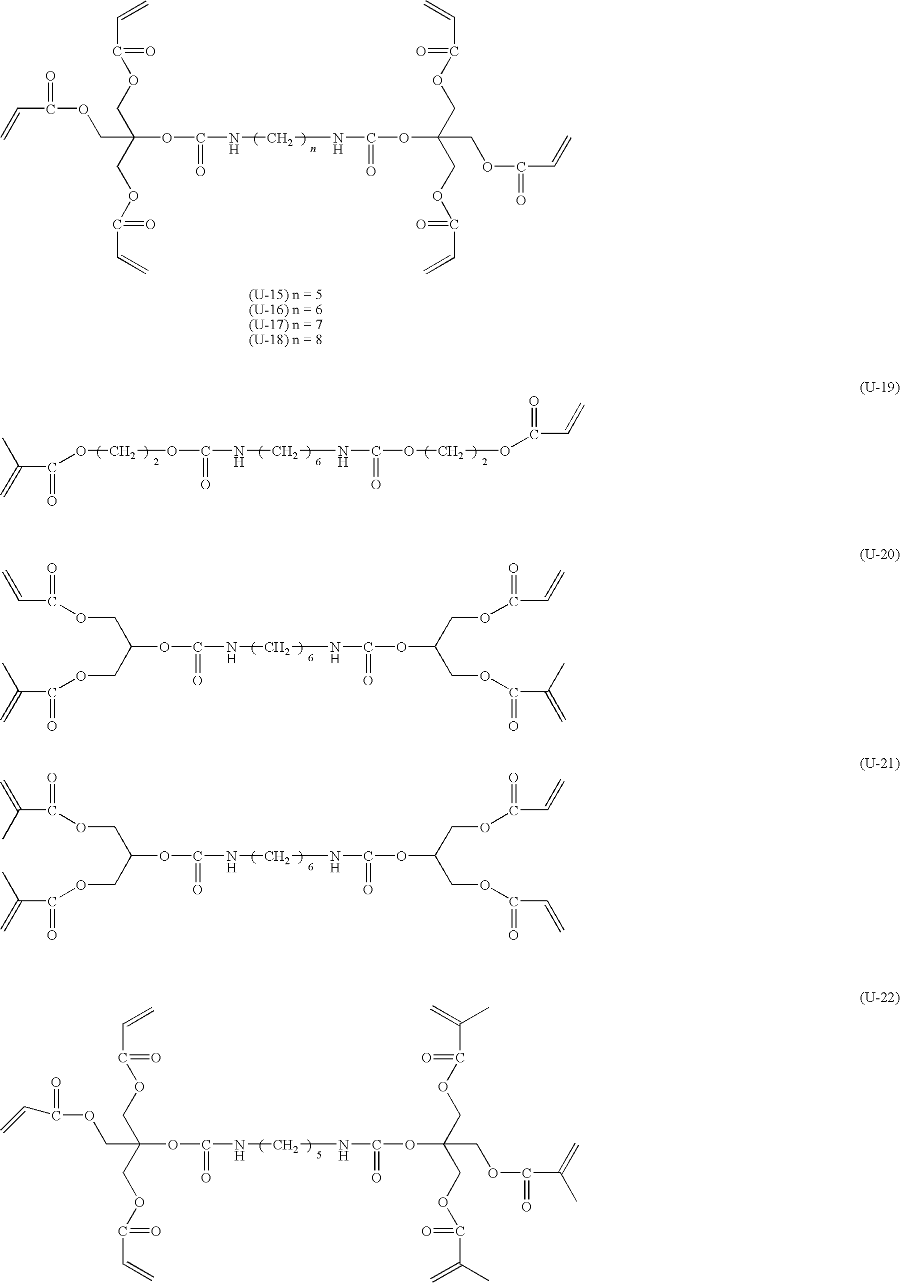

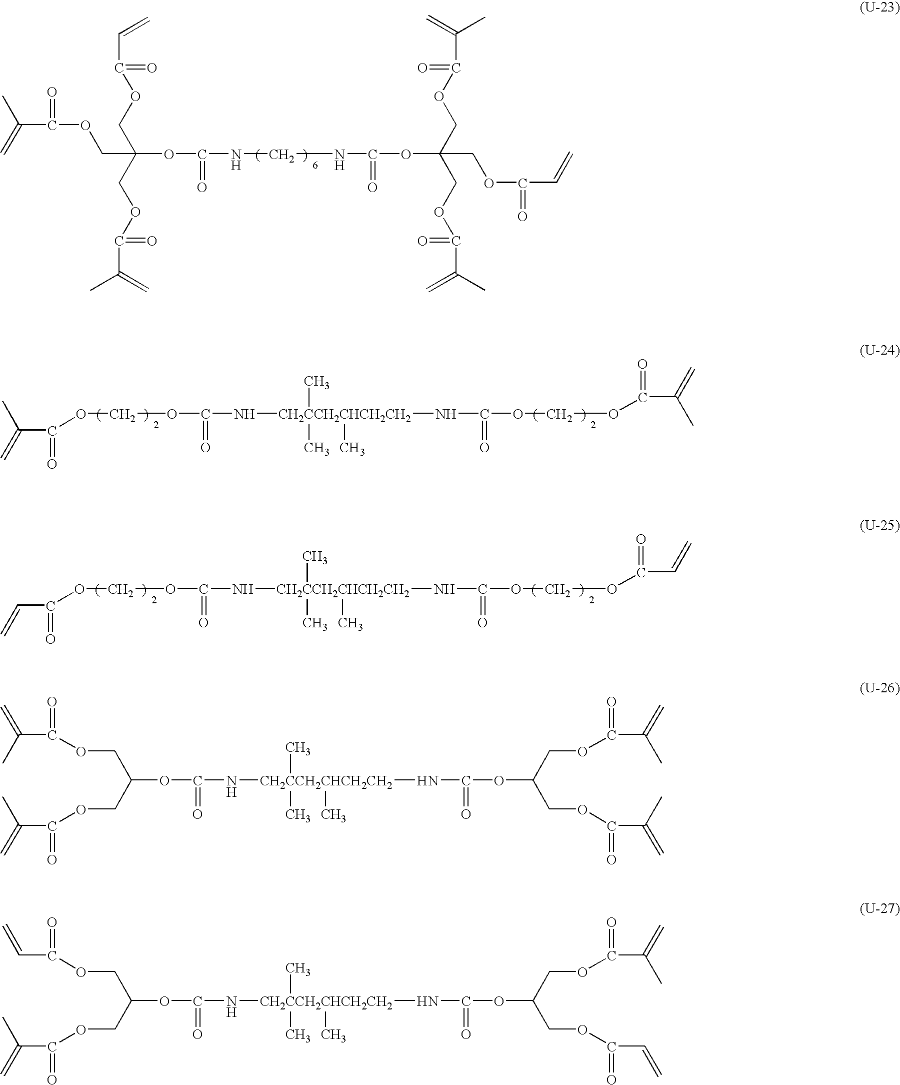

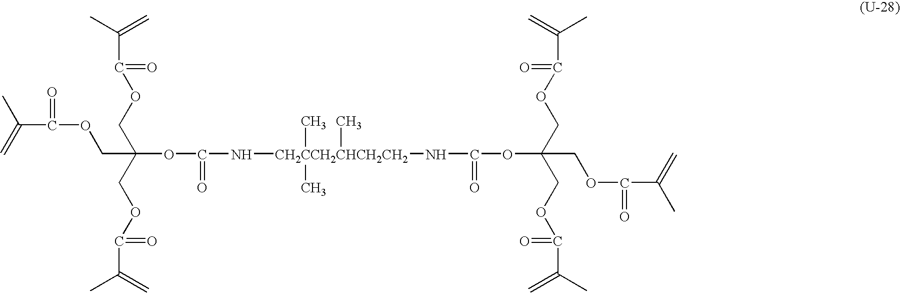

In the invention, the Polymerizable compound represented by formula (1) is used in a range from 5 to 80% by weight, more preferably from 25 to 75% by weight, based on the total solid content of the image-recording layer. In the range described above, good image formation is conducted and good printing durability is obtained.

### (B) Fine Polymer Particle Containing Structural Unit Represented by Formula (2) and Structural Unit Represented by Formula (3)

The lithographic printing plate precursor according to the invention is characterized by containing a specific fine polymer particle in the image-recording layer. The specific fine polymer particle according to the invention is a fine polymer particle containing a structural unit represented by formula (2) shown below and a structural unit represented by formula (3) shown below.

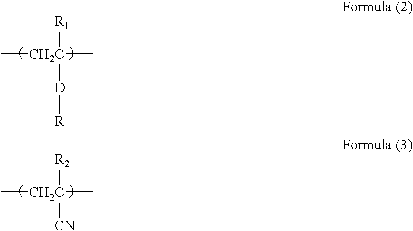

In formula (2), D represents a single bond or a —COO— group, and R represents an alkyl group having from 1 to 12 carbon atoms, an aryl group or an aralkyl group. When D is a single bond, R is preferably a phenyl group. When D is a —COO— group, R is preferably an alkyl group having from 1 to 6 carbon atoms or a benzyl group, and particularly preferably a methyl group, an ethyl group, a propyl group, a cyclohexyl group or a benzyl group. R₁ represents a hydrogen atom or a methyl group, and more preferably a hydrogen atom.

In formula (3), R₂ represents a hydrogen atom or a methyl group, and more preferably a hydrogen atom.

With respect to a ratio (copolymerization mole percent) of each structural unit contained in the fine polymer particle, the ratio of structural unit represented by formula (2) is preferably from 5 to 70% by mole, more preferably from 5 to 50% by mole, and most preferably from 10 to 30% by mole, and the ratio of structural unit represented by formula (3) is preferably from 30 to 95% by mole, more preferably from 50 to 95% by mole, and most preferably from 70 to 90% by mole.

It is preferred that the fine polymer particle according to the invention contains at least one group selected from a polyoxyethylene group, a polyoxypropylene group, a hydroxyethyl group and a hydroxypropyl group in order to improve the on-press development property. The introduction of such a group into the fine polymer particle can be conducted by copolymerization of a monomer having such a group. Specifically, the copolymerization is conducted by using a polyalkylene oxide ester of acrylic acid or methacrylic acid (for example, acrylate or methacrylate of polyethylene glycol monomethyl ether or polypropylene glycol monomethyl ether), a hydroxyalkyl ester of acrylic acid or methacrylic acid (for example, acrylate or methacrylate of ethylene glycol or propylene glycol).

The copolymerization mole percent of the above-described monomer is preferably from 1 to 30% by weight, and more preferably from 2 to 20% by weight.

Further, the fine polymer particle for use in the invention may contain a constituting unit having a heat reactive group. The heat reactive group may be a functional group capable of undergoing any reaction as far as a chemical bond is formed. Preferable examples of the heat reactive group include an ethylenically unsaturated group capable of undergoing a radical polymerization reaction (for example, an acryloyl group, a methacryloyl group, a vinyl group or an allyl group), a cationic polymerizable group (for example, a vinyl group or a vinyloxy group), an isocyanate group or block isocyanate group, an epoxy group or a vinyloxy group capable of undergoing an addition reaction and as the reaction partner, a functional group having an active hydrogen atom (for example, an amino group, a hydroxy group or a carboxyl group), a carboxyl group capable of undergoing a condensation reaction and as the reaction partner, a hydroxy group or an amino group, an acid anhydride group capable of undergoing a ring-opening addition reaction and as the reaction partner, an amino group or a hydroxy group.

The introduction of the constituting unit having a heat reactive group into the fine polymer particle can be conducted by copolymerization of a monomer having the heat reactive group or a polymer reaction.

The copolymerization mole percent of the above-described monomer is preferably from 1 to 30% by weight, and more preferably from 2 to 20% by weight.

Moreover, the fine polymer particle for use in the invention may contain a constituting unit derived from an ordinary acrylic monomer, as other component.

An average particle size of the fine polymer particle for use in the invention is preferably from 0.01 to 2.0 μm. A weight average molecular weight (Mw) of the polymer is preferably from 10,000 to 1,000,000, more preferably from 100,000 to 500,000.

The content of the fine polymer particle according to the invention is preferably from 0.1 to 10% by weight, more preferably from 0.5 to 5% by weight, and most preferably from 1 to 3% by weight, base on the total solid content of the image-recording layer.

### (C) Infrared Absorbing Agent

The infrared absorbing agent has a function of converting the infrared ray absorbed to heat and a function of being excited by the infrared ray to perform electron transfer and/or energy transfer to a polymerization initiator described hereinafter. The infrared absorbing agent for use in the invention is a dye or pigment having an absorption maximum in a wavelength range of 760 to 1,200 nm.

As the infrared absorbing agent, compounds described in Paragraph Nos. [0058] to [0087] of JP-A-2008-195018 are used.

Of these, cyanine dyes, squarylium dyes, pyrylium dyes and nickel thiolate complexes are preferred as the infrared absorbing agent. As the particularly preferable example of the dye, a cyanine dye represented by formula (b) shown below is exemplified.

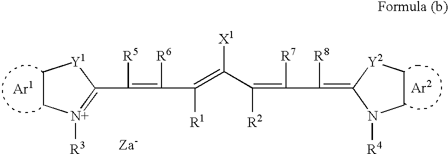

In formula (b), X¹ represents a hydrogen atom, a halogen atom, —N(R⁹)(R¹⁰), X²-L¹ or a group shown below. R⁹ and R¹⁰, which may be the same or different, each represents an aromatic hydrocarbon group having from 6 to 10 carbon atoms, which may have a substituent, an alkyl group having from 1 to 8 carbon atoms, which may have a substituent or a hydrogen atom, or R⁹ and R¹⁰ may be combined with each other to form a ring. Among them, a phenyl group is preferable. X² represents an oxygen atom or a sulfur atom, L¹ represents a hydrocarbon group having from 1 to 12 carbon atoms, an aromatic ring group containing a hetero atom or a hydrocarbon group having from 1 to 12 carbon atoms and containing a hetero atom. The hetero atom used herein indicates a nitrogen atom, a sulfur atom, an oxygen atom, a halogen atom and a selenium atom. In the group shown below, Xa⁻ has the same meaning as Za⁻ defined hereinafter, and R^{a} represents a hydrogen atom or a substituent selected from an alkyl group, an aryl group, a substituted or unsubstituted amino group and a halogen atom.

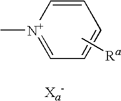

R¹ and R² each independently represents a hydrocarbon group having from 1 to 12 carbon atoms. In view of the preservation stability of a coating solution for image-recording layer, it is preferred that R¹ and R² each represents a hydrocarbon group having two or more carbon atoms. It is also preferred that R¹ and R² are combined with each other to form a 5-membered or 6-membered ring.

Ar¹ and Ar², which may be the same or different, each represents an aromatic hydrocarbon group which may have a substituent. Preferable examples of the aromatic hydrocarbon group include a benzene ring group and a naphthalene ring group. Also, preferable examples of the substituent include a hydrocarbon group having 12 or less carbon atoms, a halogen atom and an alkoxy group having 12 or less carbon atoms. Y¹ and Y², which may be the same or different, each represents a sulfur atom or a dialkylmethylene group having 12 or less carbon atoms. R³ and R⁴, which may be the same or different, each represents a hydrocarbon group having 20 or less carbon atoms, which may have a substituent. Preferable examples of the substituent include an alkoxy group having 12 or less carbon atoms, a carboxyl group and a sulfo group. R⁵, R⁶, R⁷ and R⁸, which may be the same or different, each represents a hydrogen atom or a hydrocarbon group having 12 or less carbon atoms. In view of the availability of raw materials, a hydrogen atom is preferred. Za⁻ represents a counter anion. However, Za⁻ is not necessary when the cyanine dye represented by formula (b) has an anionic substituent in the structure thereof and neutralization of charge is not needed. In view of the preservation stability of a coating solution for image-recording layer, preferable examples of the counter ion for Za⁻ include a halide ion, a perchlorate ion, a tetrafluoroborate ion, a hexafluorophosphate ion and a sulfonate ion, and particularly preferable examples thereof include a perchlorate ion, a hexafluorophosphate ion and an arylsulfonate ion.

Specific examples of the cyanine dye represented by formula (b), which can be preferably used in the invention, include those described in Paragraph Nos. [0017] to [0019] of JP-A-2001-133969, Paragraph Nos. [0012] to [0021] of JP-A-2002-23360 and Paragraph Nos. [0012] to [0037] of JP-A-2002-40638.

The infrared absorbing agents may be used individually or in combination of two or more thereof. In case of using in combination, a pigment may be used. As the pigment, compounds described in Paragraph Nos. [0072] to [0076] of JP-A-2008-195018 are preferably used.

The content of the infrared absorbing agent in the image-recording layer according to the invention is preferably from 0.1 to 10.0% by weight, more preferably from 0.5 to 5.0% by weight, based on the total solid content of the image-recording layer.

### (D) Polymerization Initiator

The polymerization initiator for use in the invention is a compound which initiates or accelerates polymerization of the radical polymerizable compound. The polymerization initiator for use in the invention is preferably a radical polymerization initiator and includes, for example, known thermal polymerization initiators, compounds containing a bond having small bond dissociation energy and photopolymerization initiators.

The polymerization initiators in the invention include, for example, (a) organic halides, (b) carbonyl compounds, (c) azo compounds, (d) organic peroxides, (e) metallocene compounds, (f) azido compounds, (g) hexaarylbiimidazole compounds, (h) organic borate compounds, (i) disulfone compounds, (j) oxime ester compounds and (k) onium salt compounds.

As the organic halides (a), compounds described in Paragraph Nos. [0022] to [0023] of JP-A-2008-195018 are preferable.

As the carbonyl compounds (b), compounds described in Paragraph No. [0024] of JP-A-2008-195018 are preferable.

As the azo compounds (c), for example, azo compounds described in JP-A-8-108621 are used.

As the organic peroxides (d), for example, compounds described in Paragraph No. [0025] of JP-A-2008-195018 are preferable.

As the metallocene compounds (e), for example, compounds described in Paragraph No. [0026] of JP-A-2008-195018 are preferable.

As the azido compounds (f), compound, for example, 2,6-bis(4-azidobenzylidene)-4-methylcyclohexanone is exemplified.

As the hexaarylbiimidazole compounds (g), for example, compounds described in Paragraph No. [0027] of JP-A-2008-195018 are preferable.

As the organic borate compounds (h), for example, compounds described in Paragraph No. [0028] of JP-A-2008-195018 are preferable.

As the disulfone compounds (i), for example, compounds described in JP-A-61-166544 and JP-A-2002-328465 are exemplified.

As the oxime ester compounds (j), for example, compounds described in Paragraph Nos. [0028] to [0030] of JP-A-2008-195018 are preferable.

As the onium salt compounds (k), onium salts, for example, diazonium salts described in S. I. Schlesinger, Photogr. Sci. Eng., 18, 387 (1974) and T. S. Bal et al., Polymer, 21, 423 (1980), ammonium salts described in U.S. Pat. No. 4,069,055 and JP-A-4-365049, phosphonium salts described in U.S. Pat. Nos. 4,069,055 and 4,069,056, iodonium salts described in European Patent 104,143, U.S. Pat. Nos. 339,049 and 410,201, U.S. Patent Publication No. 2008/0311520, JP-A-2-150848 and JP-A-2-296514, sulfonium salts described in European Patents 370,693, 390,214, 233,567, 297,443 and 297,442, U.S. Pat. Nos. 4,933,377, 161,811, 410,201, 339,049, 4,760,013, 4,734,444 and 2,833,827 and German Patents 2,904,626, 3,604,580 and 3,604,581, selenonium salts described in J. V. Crivello et al., Macromolecules, 10 (6), 1307 (1977) and J. V. Crivello et al., J. Polymer Sci., Polymer Chem. Ed., 17, 1047 (1979), arsonium salts described in C. S. Wen et al., Teh, Proc. Conf. Rad. Curing ASIA, p. 478, Tokyo, October (1988), and azinium salts described in JP-A-2008-195018 are exemplified.

Of the radical polymerization initiators, the onium salts, particularly, the iodonium salts, sulfonium salts and azinium salts are preferable. Specific examples of these compounds are set forth below, but the invention should not be construed as being limited thereto.

Of the iodonium salts, a diphenyliodonium salt is preferable, a diphenyliodonium salt substituted with an electron donating group, for example, an alkyl group or an alkoxy group is more preferable, and an asymmetric diphenyliodonium salt is still more preferable.

Examples of the iodonium salt include diphenyliodonium hexafluorophosphate, 4-methoxyphenyl-4-(2-methylpropyl)phenyliodonium hexafluorophosphate, 4-(2-methylpropyl)phenyl-p-tolyliodonium hexafluorophosphate, 4-hexyloxyphenyl-2,4,6-trimethoxyphenyliodonium hexafluorophosphate, 4-hexyloxyphenyl-2,4-diethoxyphenyliodonium tetraphenylborate, 4-octyloxyphenyl-2,4,6-trimethoxyphenyliodonium 1-perfluorobutanesulfonate, 4-octyloxyphenyl-2,4,6-trimethoxyphenyliodonium hexafluorophosphate and bis(4-tert-butylphenyl)iodonium tetraphenylborate.

Examples of the sulfonium salt include triphenylsulfonium hexafluorophosphate, triphenylsulfonium benzoylformate, bis(4-chlorophenyl)phenylsulfonium benzoylformate, bis(4-chlorophenyl)-4-methylphenylsulfonium tetrafluoroborate and tris(4-chlorophenyl)sulfonium 3,5-bis(methoxycarbonyl)benzenesulfonate.

Examples of the azinium salt include 1-cyclohexylmethyloxypyridinium hexafluorophosphate, 1-cyclohexyloxy-4-phenylpyridinium hexafluorophosphate, 1-ethoxy-4-phenylpyridinium hexafluorophosphate, 1-(2-ethylhexyloxy)-4-phenylpyridinium hexafluorophosphate, 4-chloro-1-cyclohexylmethyloxypyridinium hexafluorophosphate, 1-ethoxy-4-cyanopyridinium hexafluorophosphate, 3,4-dichloro-1-(2-ethylhexyloxy)pyridinium hexafluorophosphate, 1-benzyloxy-4-phenylpyridinium hexafluorophosphate, 1-phenethyloxy-4-phenylpyridinium hexafluorophosphate, 1-(2-ethylhexyloxy)-4-phenylpyridinium p-toluenesulfonate, 1-(2-ethylhexyloxy)-4-phenylpyridinium perfluorobutanesulfonate, 1-(2-ethylhexyloxy)-4-phenylpyridinium bromide and 1-(2-ethylhexyloxy)-4-phenylpyridinium tetrafluoroborate.

The polymerization initiator can be added to the image-recording layer preferably in an amount from 0.1 to 50% by weight, more preferably from 0.5 to 30% by weight, particularly preferably from 0.8 to 20% by weight, based on the total solid content constituting the image-recording layer. In the range described above, good sensitivity and good stain resistance in the non-image area at the time of printing are obtained.

### (E) Betaine Compound Represented by Formula (I) or (II)

The image-recording layer according to the invention preferably contains a betaine compound represented by formula (I) or (II) shown below.

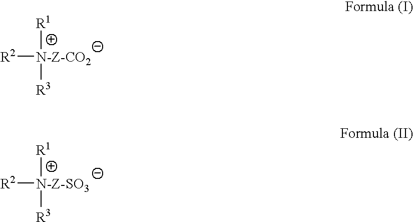

In formulae (I) and (II), R¹ to R³ each independently represents an alkyl group having from 1 to 5 carbon atoms, an alkenyl group, an alkynyl group, a cycloalkyl group or an aryl group, each of which may be substituted with a hydroxy group or an amino group, Z represents an alkylene group having from 1 to 4 carbon atoms which may be substituted with an alkyl group having 4 or less carbon atoms or a hydroxy group, or at least two of R¹ to R³ and Z may be combined with each other to from a heterocyclic ring.

By incorporating the betaine compound into the image-recording layer, it is possible to improve the on-press development property without degradation of printing durability. Of the compounds represented by formulae (I) and (II), it is preferred that R¹ to R³ each independently represents an alkyl group having from 1 to 3 carbon atoms or at least two of R¹ to R³ and Z are combined with each other to form a 5-membered or 6-membered heterocyclic ring. In particular, a compound having a quaternary ammonium skeleton in which R¹ to R³ each independently represents a methyl group or an ethyl group, or a compound having a pyrrolidine skeleton, a piperidine skeleton, a pyridine skeleton or an imidazoline skeleton each of which is formed by combining at least two of R¹ to R³ and Z in formula (I) or (II) is preferable.

Specific examples of the compound represented by formula (I) are set forth below, but the invention should not be construed as being limited thereto.

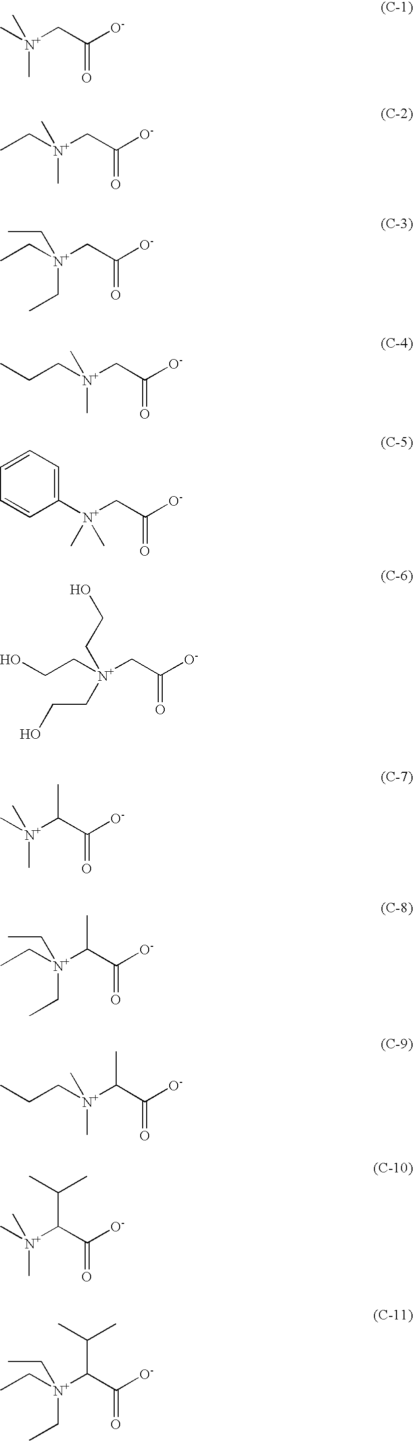

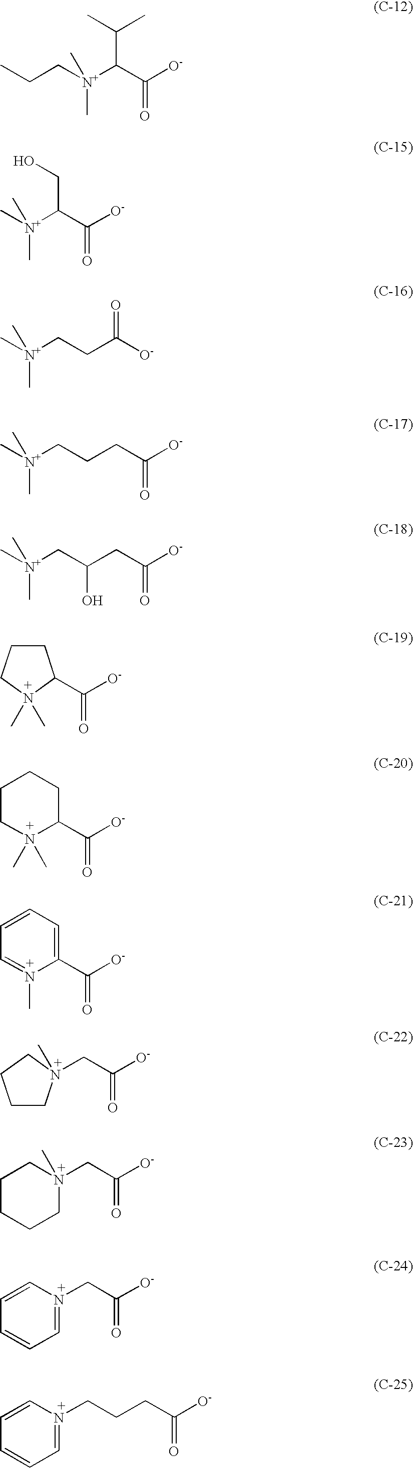

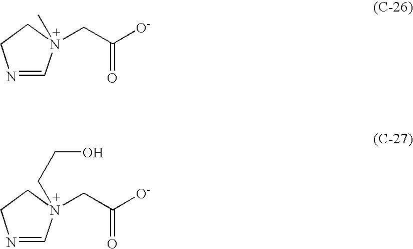

Specific examples of the compound represented by formula (II) are set forth below, but the invention should not be construed as being limited thereto.

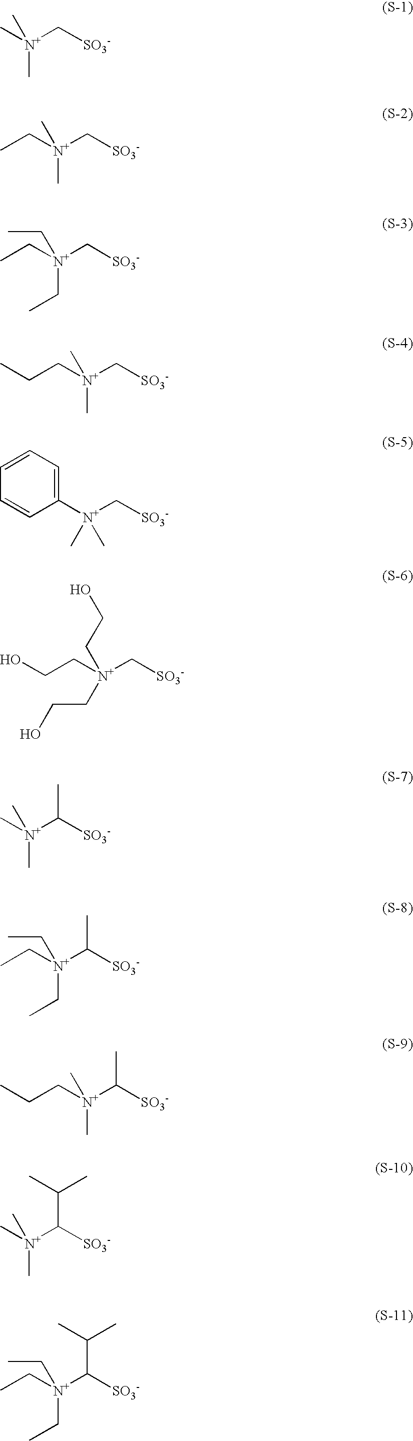

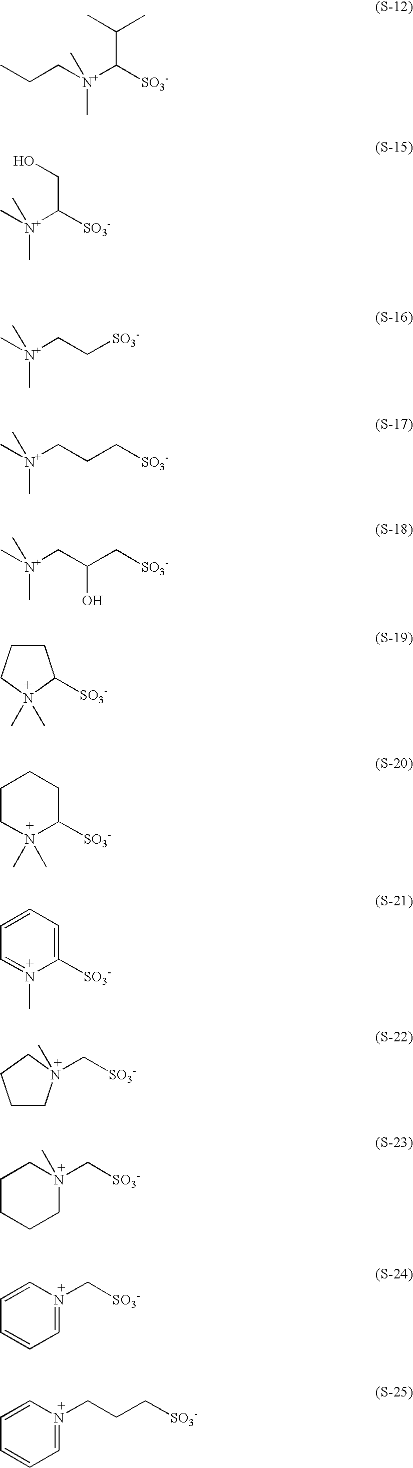

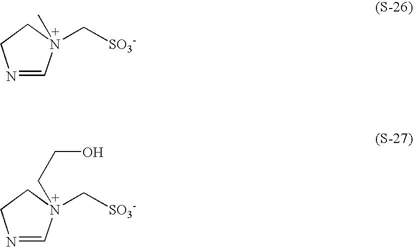

Since the compound represented by formula (I) or (II) has a small structure of hydrophobic portion and almost no surface active function, degradations of the hydrophobicity and film strength of the image area due to the penetration of dampening water into the exposed area (image area) of the image-recording layer are prevented and thus, the ink receptivity and printing durability of the image-recording layer can be preferably maintained.

The amount of the compound represented by formula (I) or (II) added to the image-recording layer is preferably from 0.1 to 10% by weight, more preferably from 0.2 to 5% by weight, still more preferably from 0.4 to 2% by weight, based on the total solid content of the image-recording layer.

The compound represented by formula (I) or (II) may be added to an undercoat layer. The amount of the compound represented by formula (I) or (II) added to the undercoat layer is preferably from 5 to 50% by weight, more preferably from 8 to 30% by weight, still more preferably from 10 to 20% by weight, based on the total solid content of the undercoat layer.

Further, the compound represented by formula (I) or (II) may be added to an overcoat layer. The amount of the compound represented by formula (I) or (II) added to the overcoat layer is preferably 10% by weight or less based on the total solid content of the overcoat layer. In the range described above, good on-press development property and good printing durability are achieved.

The compounds represented by formulae (I) and (II) may be used individually or as a mixture of two or more thereof.

### (F) Other Components

The image-recording layer according to the invention may further contain other components, if desired. For instance, a binder polymer can be used for the purpose of improving film strength of the image-recording layer. In particular, as the binder polymer preferable for the invention, a polymer having a crosslinkable functional group for improving film strength of the image area in its main chain or side chain, preferably in its side chain, as described in JP-A-2008-195018 is exemplified. Further, in order to improve the on-press development property, the image-recording layer may contain a hydrophilic low molecular weight compound described in JP-A-2008-195018. Moreover, in order to improve the ink receptivity, the image-recording layer may contain a phosphonium compound described in JP-A-2006-297907 and JP-A-2007-50660.

Other components, for example, a surfactant, a coloring agent, a print-out agent, a polymerization inhibitor, a higher fatty acid derivative, a plasticizer, a fine inorganic particle, an inorganic stratiform compound, a co-sensitizer or a chain transfer agent may further be added to the image-recording layer. Specifically, compounds and amounts added thereof described, for example, in Paragraph Nos. [0114] to [0159] of JP-A-2008-284817, Paragraph Nos. [0023] to [0027] of JP-A-2006-91479 and Paragraph No. [0060] of U.S. Patent Publication No. 2008/0311520 are preferably used.

### (G) Formation of Image-Recording Layer

The image-recording layer according to the invention is formed by dispersing or dissolving each of the necessary constituting components described above in a solvent to prepare a coating solution and coating the solution on a support by a known method, for example, bar coater coating and drying as described in Paragraph Nos. [0142] to [0143] of JP-A-2008-195018. The coating amount (solid content) of the image-recording layer formed on a support after coating and drying may be varied according to the intended purpose but is in general preferably from 0.3 to 3.0 g/m². In the range described above, good sensitivity and good film property of the image-recording layer can be achieved.

### (Overcoat Layer)

The lithographic printing plate precursor according to the invention has an overcoat layer (protective layer) on the image-recording layer. The overcoat layer has a function for preventing, for example, occurrence of scratch in the image-recording layer or ablation caused by exposure with a high illuminance laser beam, in addition to the function for avoiding an inhibition reaction against the image formation by means of oxygen blocking. The overcoat layer according to the invention preferably contains an inorganic stratiform compound. By incorporating the inorganic stratiform compound, the oxygen blocking property increases to achieve good printing durability.

Further, the overcoat layer may contain a binder, a plasticizer, a surfactant, an oil-sensitizing agent or the like.

The inorganic stratiform compound for use in the invention includes, for example, natural mica or synthetic mica as described in JP-A-2005-119273. More specifically, the inorganic stratiform compound is a particle having a thin tabular shape and includes, for instance, mica, for example, natural mica represented by the following formula:

A(B,C)₂₋₅D₄O₁₀(OH,F,O)₂

(wherein A represents any one of K, Na and Ca, B and C each represents any one of Fe (II), Fe(III), Mn, Al, Mg and V, and D represents Si or Al) or synthetic mica, talc represented by the following formula: 3MgO.4SiO.H₂O, teniolite, montmorillonite, saponite, hectolite and zirconium phosphate.

Of the micas, examples of the natural mica include muscovite, paragonite, phlogopite, biotite and lepidolite. Examples of the synthetic mica include non-swellable mica, for example, fluorphlogopite KMg₃(AlSi₃O₁₀)F₂ or potassium tetrasilic mica KMg_{2.5}(Si₄O₁₀)F₂, and swellable mica, for example, Na tetrasilic mica NaMg_{2.5}(Si₄O₁₀)F₂, Na or Li teniolite (Na, Li)Mg₂Li(Si₄O₁₀)F₂, or montmorillonite based Na or Li hectolite (Na, Li)_{1/8}Mg_{2/5}Li_{1/8}(Si₄O₁₀)F₂. Synthetic smectite is also useful.

Of the inorganic stratiform compounds, fluorine-based swellable mica, which is a synthetic inorganic stratiform compound, is particularly useful in the invention. Specifically, the swellable synthetic mica and an swellable clay mineral, for example, montmorillonite, saponite, hectolite or bentonite have a stratiform structure comprising a unit crystal lattice layer having a thickness of approximately 10 to 15 angstroms, and metallic atom substitution in the lattices thereof is remarkably large in comparison with other clay minerals. As a result, the lattice layer results in lack of positive charge and to compensate it, a cation, for example, Li⁺, Na⁺, Ca²⁺ or Mg²⁺ is adsorbed between the lattice layers. The cation present between the layers is referred to as an exchangeable cation and can be exchanged with various cations. When the cation present between the layers is Li⁺ or Na⁺, since the ion radius thereof is small, a bond between the stratiform crystal lattices is week and greatly swells with water. When share is applied under such condition, the stratiform crystal lattices are easily cleaved to form a stable sol in water. The bentnite and swellable synthetic mica have strongly such tendency and useful in the invention. In particular, the swellable synthetic mica is preferably used.

With respect to the shape of the inorganic stratiform compound for use in the invention, the thinner the thickness or the larger the plain size as long as smoothness of coated surface and transmission of actinic radiation are not damaged, the better from the standpoint of control of diffusion. Therefore, an aspect ratio of the inorganic stratiform compound is ordinarily 20 or more, preferably 100 or more, and particularly preferably 200 or more. The aspect ratio is a ratio of major axis to thickness of the particle and can be determined, for example, from a projection drawing of the particle by a microphotography. The larger the aspect ratio, the greater the effect obtained.

As for the particle diameter of the inorganic stratiform compound for use in the invention, an average major axis is ordinarily from 0.3 to 20 μm, preferably from 0.5 to 10 μm, and particularly preferably from 1 to 5 μm. An average thickness of the particle is ordinarily 0.1 μm or less, preferably 0.05 μm or less, and particularly preferably 0.01 μm or less. For example, with respect to the swellable synthetic mica which is the representative compound of the inorganic stratiform compounds, the thickness is approximately from 1 to 50 nm and the plain size is approximately from 1 to 20 μm.

When such an inorganic stratiform compound particle having a large aspect ratio is incorporated into the overcoat layer, film strength thereof increases and penetration of oxygen or moisture can be effectively inhibited so that the overcoat layer can be prevented from deterioration due to deformation, and even when the lithographic printing plate precursor is preserved for a long period of time under high humidity condition, it is prevented from decrease in the image-forming property thereof due to the change of humidity and exhibits excellent preservation stability.

The inorganic stratiform compound is dispersed to use by a dispersion method described in JP-A-2005-119273.

The content of the inorganic stratiform compound in the overcoat layer is ordinarily from 5/1 to 1/100 in terms of a weight ratio of the inorganic stratiform compound to an amount of a binder described below used in the overcoat layer. When a plural kind of the inorganic stratiform compounds is used together, it is preferred that the total amount of the inorganic stratiform compounds is in the range of weight ratio described above.

It is preferred to use a binder together with the inorganic stratiform compound in the overcoat layer.

The binder for the overcoat layer is not particularly restricted as far as it has good dispersibility of the inorganic stratiform compound and is capable of forming a uniform layer coming into close contact with the image-recording layer and any water-soluble polymer and water-insoluble polymer can be appropriately selected to use. Specifically, a water-soluble polymer, for example, polyvinyl alcohol, a modified polyvinyl alcohol, polyvinyl pyrrolidone, polyvinyl imidazole, polyacrylic acid, polyacrylamide, a partially saponified product of polyvinyl acetate, an ethylene-vinyl alcohol copolymer, a water-soluble cellulose derivative, gelatin, a starch derivative or gum arabic, and a polymer, for example, polyvinylidene chloride, poly(meth)acrylonitrile, polysulfone, polyvinyl chloride, polyethylene, polycarbonate, polystyrene, polyamide or cellophane are exemplified. The polymers may be used in combination of two or more thereof, if desired.

From the standpoint of ease of removal of the overcoat layer remaining in the non-image area and handling property at the formation of layer, a water-soluble polymer is preferable. For instance, polyvinyl alcohol, polyvinyl pyrrolidone, polyvinyl imidazole, a water-soluble acrylic resin, for example, polyacrylic acid, gelatin or gum arabic is preferable, and polyvinyl alcohol, polyvinyl pyrrolidone, gelatin or gum arabic is more preferable from the standpoint of ease of removal with dampening water at the printing.

The polyvinyl alcohol for use in the overcoat layer according to the invention may be partially substituted with ester, ether or acetal as far as it contains a substantial amount of unsubstituted vinyl alcohol units necessary for maintaining water solubility. Also, the polyvinyl alcohol may partially contain other copolymerization components. For instance, polyvinyl alcohols of various polymerization degrees having at random a various kind of hydrophilic modified cites, for example, an anion-modified cite modified with an anion, e.g., a carboxyl group or a sulfo group, a cation-modified cite modified with a cation, e.g., an amino group or an ammonium group, a silanol-modified cite or a thiol-modified cite, and polyvinyl alcohols of various polymerization degrees having at the terminal of the polymer chain a various kind of modified cites, for example, the above-described anion-modified cite, cation modified cite, silanol-modified cite or thiol-modified cite, an alkoxy-modified cite, a sulfide-modified cite, an ester modified cite of vinyl alcohol with a various kind of organic acids, an ester modified cite of the above-described anion-modified cite with an alcohol or an epoxy-modified cite are also preferably used.

Preferable examples of the polyvinyl alcohol include those having a hydrolysis degree of 71 to 100% by mole and a polymerization degree of 300 to 2,400. Specific examples of the polyvinyl alcohol include PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-2205, PVA-224E, PVA-405, PVA-420, PVA-613 and L-8, produced by Kuraray Co., Ltd. Specific examples of the modified polyvinyl alcohol include that having an anion-modified cite, for example, KL-318, KL-118, KM-618, KM-118 or SK-5102, that having a cation-modified cite, for example, C-318, C-118 or CM-318, that having a terminal thiol-modified cite, for example, M-205 or M-115, that having a terminal sulfide-modified cite, for example, MP-103, MP-203, MP-102 or MP-202, that having an ester-modified cite with a higher fatty acid at the terminal, for example, HL-12E or HL-1203 and that having a reactive silane-modified cite, for example, R-1130, R-2105 or R-2130, all produced by Kuraray Co., Ltd.

Further, the overcoat layer may contain a known additive, for example, a plasticizer for imparting flexibility, a surfactant for improving a coating property or a fine inorganic particle for controlling a surface slipping property. The oil-sensitizing agent described with respect to the image-recording layer may also be incorporated into the overcoat layer.

The overcoat layer is coated according to a known method, for example, a method described in JP-A-2005-119273. The coating amount of the overcoat layer is preferably in a range of 0.01 to 10 g/m², more preferably in a range of 0.02 to 3 g/m², most preferably in a range of 0.02 to 1 g/m², in terms of the coating amount after drying.

### (Undercoat Layer)

In the lithographic printing plate precursor according to the invention, an undercoat layer (also referred to as an intermediate layer) is preferably provided between the image-recording layer and the support. The undercoat layer strengthens adhesion between the support and the image-recording layer in the exposed area and makes removal of the image-recording layer from the support in the unexposed area easy, thereby contributing improvement in the developing property without accompanying degradation of the printing durability. Further, it is advantageous that in the case of infrared laser exposure, since the undercoat layer acts as a heat insulating layer, decrease in sensitivity due to diffusion of heat generated upon the exposure into the support is prevented.

The undercoat layer according to the invention preferably contains a polymer compound having a substrate adsorbing group capable of adsorbing to a surface of the support and a polymerizable group as described in JP-A-2005-125749 and JP-A-2006-188038. It is further preferred that the polymer compound has a hydrophilic group. The polymer compound is preferably a copolymer of a monomer having an adsorbing group, a monomer having a polymerizable group and, if desired, a monomer having a hydrophilic group. More specifically, a polymer compound which is a copolymer of a monomer having an adsorbing group, for example, a phenolic hydroxy group, a carboxyl group, —PO₃H₂, —OPO₃H₂, —CONHSO₂—, —SO₂NHSO₂— and —COCH₂COCH₃, a monomer having a polymerizable group, for example, a methacryl group or an allyl group and a monomer having a hydrophilic sulfo group is exemplified. The polymer compound may contain a polymerizable group introduced by a salt formation between a polar substituent of the polymer compound and a compound containing a substituent having a counter charge to the polar substituent of the polymer compound and an ethylenically unsaturated bond and also may be further copolymerized with a monomer other than those described above, preferably a hydrophilic monomer.

The content of the polymerizable group (unsaturated double bond) in the polymer compound for undercoat layer is preferably from 0.1 to 10.0 mmol, most preferably from 2.0 to 5.5 mmol, based on 1 g of the polymer compound.

A weight average molecular weight of the polymer compound for undercoat layer is preferably 5,000 or more, and more preferably from 10,000 to 300,000.

In the undercoat layer according to the invention, a silane coupling agent having an addition-polymerizable ethylenic double bond reactive group described in JP-A-10-282679 or a phosphorus compound having an ethylenic double bond reactive group described in JP-A-2-304441 may be used together with the polymer compound described above.

The undercoat layer according to the invention may contain a chelating agent, a secondary or tertiary amine, a polymerization inhibitor or a compound containing an amino group or a functional group having polymerization inhibition ability and a group capable of interacting with a surface of aluminum support (for example, 1,4-diazobicyclo[2,2,2]octane (DABCO), 2,3,5,6-tetrahydroxy-p-quinone, chloranil, sulfophthalic acid, hydroxyethylethylenediaminetriacetic acid, dihydroxyethylethylenediaminediacetic acid or hydroxyethyliminodiacetic acid) in order to prevent the occurrence of stain due to preservation of the lithographic printing plate precursor.

The undercoat layer is coated according to a known method. The coating amount (solid content) of the undercoat layer is preferably from 0.1 to 100 mg/m², and more preferably from 1 to 30 mg/m².

### (Support)

As the support for use in the lithographic printing plate precursor according to the invention, a known support is used. Particularly, an aluminum plate subjected to roughening treatment and anodizing treatment according to a known method is preferable.

Also, other treatments, for example, an enlarging treatment or a sealing treatment of micropores of the anodized film described in JP-A-2001-253181 and JP-A-2001-322365 or a surface hydrophilizing treatment, for example, with an alkali metal silicate as described in U.S. Pat. Nos. 2,714,066, 3,181,461, 3,280,734 and 3,902,734 or polyvinyl phosphonic acid as described in U.S. Pat. Nos. 3,276,868, 4,153,461 and 4,689,272 may be appropriately selected and applied to the aluminum plate, if desired.

The support preferably has a center line average roughness of 0.10 to 1.2 μm.

The support may have a backcoat layer containing an organic polymer compound described in JP-A-5-45885 or an alkoxy compound of silicon described in JP-A-5-45885, provided on the back surface thereof, if desired.

### [Plate Making Method]

Plate making of the lithographic printing plate precursor according to the invention is preferably performed by an on-press development method. The on-press development method includes a step in which the lithographic printing plate precursor is imagewise exposed and a printing step in which oily ink and an aqueous component are supplied to the exposed lithographic printing plate precursor without undergoing any development processing to perform printing, and it is characterized in that the unexposed area of the lithographic printing plate precursor is removed in the course of the printing step. The imagewise exposure may be performed on a printing machine after the lithographic printing plate precursor is mounted on the printing machine or may be separately performed using a platesetter or the like. In the latter case, the exposed lithographic printing plate precursor is mounted as it is on a printing machine without undergoing a development processing step. Then, the printing operation is initiated using the printing machine with supplying oily ink and an aqueous component and at an early stage of the printing the on-press development is carried out. Specifically, the image-recording layer in the unexposed area is removed and the hydrophilic surface of support is revealed therewith to form the non-image area. As the oily ink and aqueous component, printing ink and dampening water, for conventional lithographic printing can be employed, respectively.

The on-press development method is described in more detail below.

As the light source used for the image exposure in the invention, a laser is preferable. The laser for use in the invention is not particularly restricted and includes, for example, a solid laser or semiconductor laser emitting an infrared ray having a wavelength of 760 to 1,200 nm.

With respect to the infrared ray laser, the output is preferably 100 mW or more, the exposure time per pixel is preferably within 20 microseconds, and the irradiation energy is preferably from 10 to 300 mJ/cm². With respect to the laser exposure, in order to shorten the exposure time, it is preferred to use a multibeam laser device.

The exposed lithographic printing plate precursor is mounted on a plate cylinder of a printing machine. In case of using a printing machine equipped with a laser exposure apparatus, the lithographic printing plate precursor is mounted on a plate cylinder of the printing machine and then subjected to the imagewise exposure.

When dampening water and printing ink are supplied to the imagewise exposed lithographic printing plate precursor to perform printing, in the exposed area of the image-recording layer, the image-recording layer cured by the exposure forms the printing ink receptive area having the oleophilic surface. On the other hand, in the unexposed area, the uncured image-recording layer is removed by dissolution or dispersion with the dampening water and/or printing ink supplied to reveal the hydrophilic surface in the area. As a result, the dampening water adheres on the revealed hydrophilic surface and the printing ink adheres to the exposed area of the image-recording layer, whereby printing is initiated.

While either the dampening water or printing ink may be supplied at first on the surface of lithographic printing plate precursor, it is preferred to supply the printing ink at first in view of preventing the dampening water from contamination with the component of the image-recording layer removed.

Thus, the lithographic printing plate precursor according to the invention is subjected to the on-press development on an offset printing machine and used as it is for printing a large number of sheets.

### EXAMPLES

The present invention will be described in more detail with reference to the following examples, but the invention should not be construed as being limited thereto.

### Examples 1 to 10 and Comparative Examples 1 to 7

### 1. Preparation of Lithographic Printing Plate Precursor (1)

### (1) Preparation of Support

An aluminum plate (material: JIS A 1050) having a thickness of 0.3 mm was subjected to a degreasing treatment at 50° C. for 30 seconds using a 10% by weight aqueous sodium aluminate solution in order to remove rolling oil on the surface thereof and then grained the surface thereof using three nylon brushes embedded with bundles of nylon bristle having a diameter of 0.3 mm and an aqueous suspension (specific gravity: 1.1 g/cm³) of pumice having a median size of 25 μm, followed by thorough washing with water. The plate was subjected to etching by immersing it in a 25% by weight aqueous sodium hydroxide solution of 45° C. for 9 seconds, washed with water, then immersed in a 20% by weight aqueous nitric acid solution at 60° C. for 20 seconds, and washed with water. The etching amount of the grained surface was about 3 g/m².

Then, using an alternating current of 60 Hz, an electrochemical roughening treatment was continuously carried out on the plate. The electrolytic solution used was a 1% by weight aqueous nitric acid solution (containing 0.5% by weight of aluminum ion) and the temperature of electrolytic solution was 50° C. The electrochemical roughening treatment was conducted using an alternating current source, which provides a rectangular alternating current having a trapezoidal waveform such that the time TP necessary for the current value to reach the peak from zero was 0.8 msec and the duty ratio was 1:1, and using a carbon electrode as a counter electrode. A ferrite was used as an auxiliary anode. The current density was 30 A/dm² in terms of the peak value of the electric current, and 5% of the electric current flowing from the electric source was divided to the auxiliary anode. The quantity of electricity in the nitric acid electrolysis was 175 C/dm² in terms of the quantity of electricity when the aluminum plate functioned as an anode. The plate was then washed with water by spraying.

The plate was further subjected to an electrochemical roughening treatment in the same manner as in the nitric acid electrolysis above using as an electrolytic solution, a 0.5% by weight aqueous hydrochloric acid solution (containing 0.5% by weight of aluminum ion) having temperature of 50° C. and under the condition that the quantity of electricity was 50 C/dm² in terms of the quantity of electricity when the aluminum plate functioned as an anode. The plate was then washed with water by spraying.

The plate was then subjected to an anodizing treatment using as an electrolytic solution, a 15% by weight aqueous sulfuric acid solution (containing 0.5% by weight of aluminum ion) at a current density of 15 A/dm² to form a direct current anodized film of 2.5 g/m², washed with water and dried to prepare Support (1).

Thereafter, in order to ensure the hydrophilicity of the non-image area, Support (1) was subjected to silicate treatment using a 2.5% by weight aqueous sodium silicate No. 3 solution at 60° C. for 10 seconds. Subsequently, the plate was washed with water to obtain Support (2). The adhesion amount of Si was 10 mg/m². The center line average roughness (Ra) of the support was measured using a stylus having a diameter of 2 μm and found to be 0.51 μm.

### (2) Formation of Undercoat Layer

Coating solution (1) for undercoat layer shown below was coated on Support (2) so as to have a dry coating amount of 20 mg/m² to prepare a support having the undercoat layer.

### <Coating Solution (1) for Undercoat Layer>

| | |
|---|---|
| Compound (1) for undercoat layer having | 0.18 g |
| structure shown below | |
| Hydroxyethyliminodiacetic acid | 0.10 g |
| Methanol | 55.24 g |
| Water | 6.15 g |

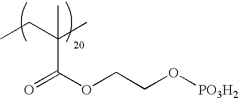

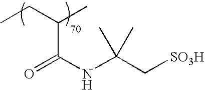

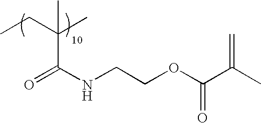

(Mw: 100,000)?
Compound (1) for undercoat layer?

### (3) Formation of Image-Recording Layer

Coating solution (1) for image-recording layer having the composition shown below was coated on the support provided with the undercoat layer described above by a bar and dried in an oven at 70° C. for 60 seconds to form an image-recording layer having a dry coating amount of 0.6 g/m².

### <Coating Solution (1) for Image-Recording Layer>

| | |
|---|---|
| Aqueous dispersion of fine polymer particle | 20.0 g |
| shown below | |
| Infrared absorbing agent (1) having structure | 0.2 g |
| shown below | |
| Polymerization initiator (Irgacure 250, | 0.5 g |
| produced by Ciba Specialty Chemicals, Inc. ) | |
| Compound represented by formula (1): Compound | 1.50 g |
| (U-20) described hereinbefore | |
| [Radical polymerizable compound (U-4HA, | |
| produced by Shin-Nakamura Chemical Co., Ltd.)] | |
| Mercapto-3-triazole | 0.2 g |
| BYK 336 (produced by BYK-Chemie GmbH) | 0.4 g |
| Klucel M (produced by Hercules Chemical Co., | 4.8 g |
| Inc.) | |
| Elvacite 4026 (produced by Ineos Acrylics | 2.5 g |
| Inc.) | |
| n-Propanol | 55.0 g |
| 2-Butanone | 17.0 g |

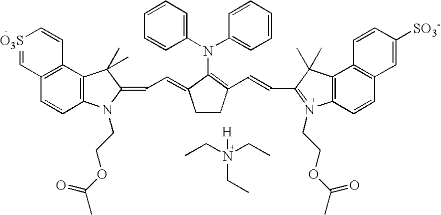

Infrared Absorbing Agent (1)

The compounds indicated using their trade names in the composition above are shown below.

### Irgacure 250:

(4-Methoxyphenyl) [4-(2-methylpropyl)phenyl]iodonium hexafluorophosphate (75% by weight propylene carbonate solution)
SR-399: Dipentaerythritol pentaacrylate
BYK 336: Modified dimethylpolysiloxane copolymer (25% by weight xylene/methoxypropyl acetate solution)
Klucel M: Hydroxypropyl cellulose (2% by weight aqueous solution)
Elvacite 4026: Highly branched polymethyl methacrylate (10% by weight 2-butanone solution)

### (Preparation of Aqueous Dispersion of Fine Polymer Particle)

A stirrer, a thermometer, a dropping funnel, a nitrogen inlet tube and a reflux condenser were attached to a 1,000 ml four-neck flask and while carrying out deoxygenation by introduction of nitrogen gas, 20 g of polyethylene glycol methyl ether methacrylate (PEGMA) (average number of repeating unit of ethylene glycol: 50), 200 g of distilled water and 200 g of n-propanol were charged therein and heated until the internal temperature reached 70° C. Then, a mixture of 10 g of styrene (St) 80 g of acrylonitrile (AN) and 0.8 g of 2,2′-azobisisobutyronitrile previously prepared was dropwise added to the flask over a period of one hour. After the completion of the dropwise addition, the reaction was continued as it was for 5 hours. Then, 0.4 g of 2,2′-azobisisobutyronitrile was added and the internal temperature was raised to 80° C. Thereafter, 0.5 g of 2,2′-azobisisobutyronitrile was added over a period of 6 hours. At the stage after reacting for 20 hours in total, the polymerization proceeded 98% or more to obtain an aqueous dispersion of fine polymer particle of PEGMA/St/AN (Oct. 10, 1980 in a weight ratio). The particle size of the fine polymer particle was 150 nm.

The particle size distribution was determined by taking an electron microphotograph of the fine polymer particle, measuring particle sizes of 5,000 fine particles in total on the photograph, and dividing a range from the largest value of the particle size measured to 0 on a logarithmic scale into 50 parts to obtain occurrence frequency of each particle size by plotting. With respect to the aspherical particle, a particle size of a spherical particle having a particle area equivalent to the particle area of the aspherical particle on the photograph was defined as the particle size.

### (4) Formation of Overcoat Layer (1)

Coating solution (1) for overcoat layer having the composition shown below was coated on the image-recording layer described above by a bar and dried in an oven at 120° C. for 60 seconds to form an overcoat layer having a dry coating amount of 0.15 g/m², thereby preparing Lithographic printing plate precursor (1).

### <Coating Solution (1) for Overcoat Layer>

| | |
|---|---|
| Dispersion of inorganic stratiform compound | 1.5 g |
| (1) shown below | |
| Aqueous 6% by weight solution of polyvinyl | 0.55 g |
| alcohol (CKS 50, sulfonic acid-modified, | |
| saponification degree: 99% by mole or more, | |
| polymerization degree: 300, produced by Nippon | |
| Synthetic Chemical Industry Co., Ltd.) | |
| Aqueous 6% by weight solution of polyvinyl | 0.03 g |
| alcohol (PVA-405, saponification degree: | |
| 81.5% by mole, polymerization degree: 500, | |
| produced by Kuraray Co., Ltd.) | |
| Aqueous 1% by weight solution of surfactant | 0.86 g |
| (Emalex 710, produced by Nihon Emulsion Co., | |
| Ltd.) | |
| Ion-exchanged water | 6.0 g |

### <Preparation of Dispersion of Inorganic Stratiform Compound (1)>

To 193.6 g of ion-exchanged water was added 6.4 g of synthetic mica (Somasif ME-100, produced by CO—OP Chemical Co., Ltd.) and the mixture was dispersed using a homogenizer until an average particle size (according to a laser scattering method) became 3 μm to prepare Dispersion of inorganic stratiform compound (1). The aspect ratio of the inorganic particle thus-dispersed was 100 or more.

### 2. Preparation of Lithographic Printing Plate Precursors (2) to (6)

Lithographic printing plate precursors (2) to (6) were prepared in the same manner as in the preparation of Lithographic printing plate precursor (1) except for changing the radical polymerizable compound of U-4HA (produced by Shin-Nakamura Chemical Co., Ltd.) in the coating solution (1) for image-recording layer to Compounds (U-2), (U-5), (U-16), (U-24) and (U-27) described hereinbefore, respectively.

### 3. Preparation of Lithographic Printing Plate Precursor (7)

Lithographic printing plate precursor (7) was prepared in the same manner as in the preparation of Lithographic printing plate precursor (1) except for further adding 0.1 g of betaine compound of Compound (C-1) described hereinbefore to the coating solution (1) for image-recording layer.

### 4. Preparation of Lithographic Printing Plate Precursor (8)

Lithographic printing plate precursor (8) was prepared in the same manner as in the preparation of Lithographic printing plate precursor (1) except for further adding 0.1 g of betaine compound of Compound (S-1) described hereinbefore to the coating solution (1) for image-recording layer.

### 5. Preparation of Lithographic Printing Plate Precursor (9)

Lithographic printing plate precursor (9) was prepared in the same manner as in the preparation of Lithographic printing plate precursor (1) except for omitting the coating of undercoat layer in the preparation of Lithographic printing plate precursor (1).

### 6. Preparation of Lithographic Printing Plate Precursor (10)

Lithographic printing plate precursor (10) for Comparative Example 1 was prepared in the same manner as in the preparation of Lithographic printing plate precursor (1) except for changing the radical polymerizable compound of U-4HA in the coating solution (1) for image-recording layer to tris(acryloyloxyethyl) isocyanurate (NK Ester A-9300, produced by Shin-Nakamura Chemical Co., Ltd.).

### 7. Preparation of Lithographic Printing Plate Precursor (11)

Lithographic printing plate precursor (11) for Comparative Example 2 was prepared in the same manner as in the preparation of Lithographic printing plate precursor (1) except for omitting the coating of overcoat layer after the formation of image-recording layer.

### 8. Preparation of Lithographic Printing Plate Precursor (12)

Lithographic printing plate precursor (12) was prepared in the same manner as in the preparation of Lithographic printing plate precursor (1) except for eliminating Dispersion of inorganic stratiform compound (1) from Coating solution (1) for overcoat layer.

### 9. Preparation of Lithographic Printing Plate Precursor (13)

Lithographic printing plate precursor (13) for Comparative Example 3 was prepared in the same manner as in the preparation of Lithographic printing plate precursor (1) except for eliminating the aqueous dispersion of fine polymer particle from Coating solution (1) for image-recording layer.

### 10. Preparation of Lithographic Printing Plate Precursors (14) to (17)

Lithographic printing plate precursors (14) to (17) for Comparative Examples 4 to 7 were prepared in the same manner as in the preparation of Lithographic printing plate precursor (1) except for changing the radical polymerizable compound of U-4HA in the coating solution (1) for image-recording layer to Compounds (A) to (D) shown below, respectively.

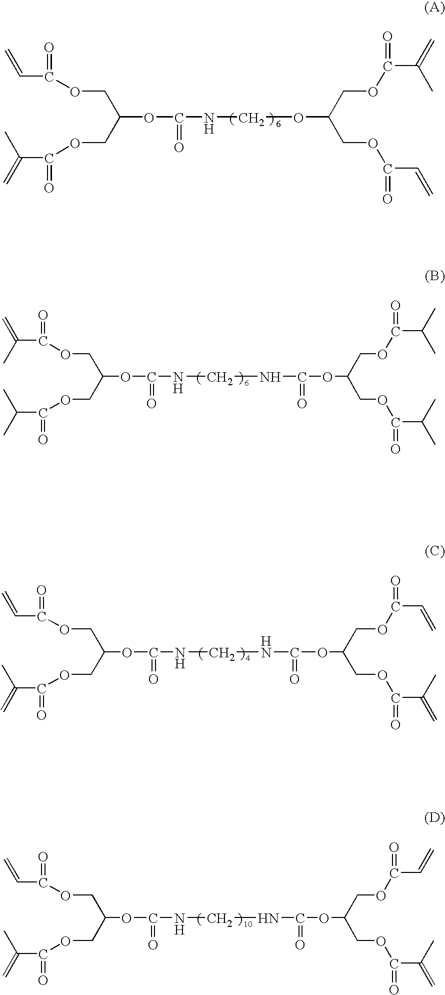

The on-press development property and printing durability of Lithographic printing plate precursors (1) to (17) thus obtained were evaluated in the following manner. The results obtained are shown in Table 1.

### (1) On-Press Development Property

Each of the lithographic printing plate precursors thus-obtained was exposed by Luxel Platesetter T-6000III equipped with an infrared semiconductor laser, produced by Fuji Film Co., Ltd. under the conditions of a rotational number of an outer surface drum of 1,000 rpm, laser output of 70% and resolution of 2,400 dpi. The exposed image contained a solid image and a 50% halftone dot chart of a 20 μm-dot FM screen.

The exposed lithographic printing plate precursor was mounted without undergoing development processing on a plate cylinder of a printing machine (Lithrone 26, produced by Komori Corp.). Using dampening water (Ecolity-2 (produced by Fuji Film Co., Ltd.)/tap water=2/98 (volume ratio)) and Values-G (N) Black Ink (produced by Dainippon Ink & Chemicals, Inc.), the dampening water and ink were supplied according to the standard automatic printing start method of Lithrone 26 to conduct printing on 100 sheets of Tokubishi art paper (76.5 kg) at a printing speed of 10,000 sheets per hour.

A number of the printing papers required until the on-press development of the unexposed area of the image-recording layer on the printing machine was completed to reach a state where the ink was not transferred to the printing paper in the non-image area was measured to evaluate the on-press development property.

### (2) Printing Durability

After performing the evaluation for the on-press development property described above, the printing was continued. As the increase in a number of printing papers, the image-recording layer was gradually abraded to cause decrease in the ink density on the printing paper. A number of printing papers wherein a value obtained by measuring a halftone dot area rate of the 50% halftone dot of FM screen on the printing paper using a Gretag densitometer decreased by 5% from the value measured on the 100^{th} paper of the printing was determined to evaluate the printing durability.

TABLE 1
Evaluation Results

| | | On-press | |
|---|---|---|---|
| | Lithographic | Development | Printing |
| | Printing Plate | Property | Durability |
| | Precursor | (sheets) | (×10⁴ sheets) |
| Example 1 | (1) | 12 | 7.5 |
| Example 2 | (2) | 13 | 6.5 |
| Example 3 | (3) | 12 | 7.0 |
| Example 4 | (4) | 15 | 7.5 |
| Example 5 | (5) | 12 | 8.0 |
| Example 6 | (6) | 13 | 8.0 |
| Example 7 | (7) | 10 | 6.0 |
| Example 8 | (8) | 10 | 7.0 |
| Example 9 | (9) | 15 | 5.5 |
| Example 10 | (12) | 12 | 6.5 |
| Comparative | (10) | 20 | 4.5 |
| Example 1 | | | |
| Comparative | (11) | 12 | 1.5 |
| Example 2 | | | |
| Comparative | (13) | 60 | 5.5 |
| Example 3 | | | |
| Comparative | (14) | 15 | 3.5 |
| Example 4 | | | |
| Comparative | (15) | 20 | 1.5 |
| Example 5 | | | |
| Comparative | (16) | 20 | 4.0 |
| Example 6 | | | |
| Comparative | (17) | 20 | 4.0 |
| Example 7 | | | |

As is apparent from the results shown in Table 1, the lithographic printing plate precursor of on-press development type which is excellent in the on-press development property and printing durability can be obtained according to the invention.

What is claimed is:

1. A lithographic printing plate precursor comprising in the following order:
a support;
an image-recording layer which is capable of being removed with at least one of printing ink and dampening water and comprises a polymerizable compound represented by the following formula (1), a polymer particle containing a structural unit represented by the following formula (2) and a structural unit represented by the following formula (3), an infrared absorbing agent and a polymerization initiator; and
an overcoat layer: 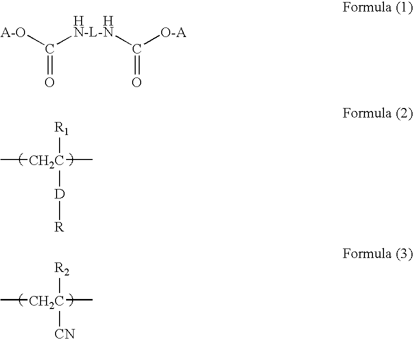
wherein, A represents a group comprising from 1 to 3 ethylenically unsaturated groups, L represents an alkylene group having from 5 to 9 carbon atoms, R represents an alkyl group having from 1 to 12 carbon atoms, an aryl group or an aralkyl group, D represents a single bond or a —COO— group, and R₁ and R₂ each independently represents a hydrogen atom or a methyl group.

2. The lithographic printing plate precursor as claimed in claim 1, wherein the overcoat layer comprises an inorganic stratiform compound.

3. The lithographic printing plate precursor as claimed in claim 1, which further comprises an undercoat layer between the support and the image-recording layer, the undercoat layer comprising a polymer compound having a support-adsorbing group and a polymerizable group.

4. The lithographic printing plate precursor as claimed in claim 1, wherein the image-recording layer comprises at least one of a betaine compound represented by the following formula (I) and a betaine compound represented by the following formula (II): 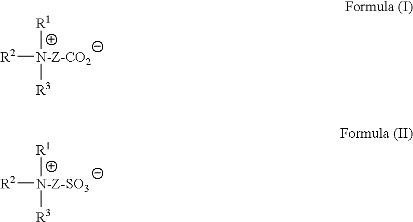
wherein, R¹ to R³ each independently represents an alkyl group having from 1 to 5 carbon atoms, an alkenyl group, an alkynyl group, a cycloalkyl group or an aryl group, each of which may be substituted with a hydroxy group or an amino group, Z represents an alkylene group having from 1 to 4 carbon atoms which may be substituted with an alkyl group having 4 or less carbon atoms or a hydroxy group, or at least two of R¹ to R³ and Z may be combined with each other to from a heterocyclic ring.

5. The lithographic printing plate precursor as claimed in claim 2, wherein the inorganic stratiform compound is swellable synthetic mica.

6. The lithographic printing plate precursor as claimed in claim 1, wherein the polymer particle has an average particle size of from 0.01 to 2.0 μm.

7. The lithographic printing plate precursor as claimed in claim 1, wherein the polymer particle has a weight average molecular weight of from 10,000 to 1,000,000.

8. A plate making method comprising:
mounting the lithographic printing plate precursor as claimed in claim 1 on a printing machine and exposing imagewise the mounted lithographic printing plate precursor with infrared laser or exposing imagewise the lithographic printing plate precursor as claimed in claim 1 and mounting the exposed lithographic printing plate precursor on a printing machine; and
supplying at least one of printing ink and dampening water to the lithographic printing plate precursor to remove an infrared unexposed area of the image-recording layer.
